(19) United States
(12) Patent Application Publication
(10) Pub. No.: US 2007/0182029 A1
(43) Pub. Date: Aug. 9, 2007

(54) SEMICONDUCTOR COMPONENT AND METHOD FOR PRODUCING SEMICONDUCTOR COMPONENTS

(75) Inventors: Martin Franosch, Muenchen (DE); Andreas Meckes, Muenchen (DE); Edward Fuergut, Dasing (DE)

Correspondence Address: DICKE, BILLIG & CZAJA, FIFTH STREET TOWERS, 100 SOUTH FIFTH STREET, SUITE 2200, MINNEAPOLIS, MN, 55402, US

(73) Assignee: INFINEON TECHNOLOGIES AG, Muenchen (DE)

(21) Appl. No.: 11/672,760

(22) Filed: Feb. 8, 2007

Related U.S. Application Data
(60) Provisional application No. 60/771,245, filed on Feb. 8, 2006.

(30) Foreign Application Priority Data
Feb. 8, 2006 (DE) 10 2006 005 994.8

(51) Int. Cl. H01L 23/29

(52) U.S. Cl. 257/793

(57) ABSTRACT

A semiconductor is disclosed. In one embodiment, the semiconductor includes a semiconductor substrate having an active area region, a covering configured to protect the active area region, and a carrier. An interspace is located between the carrier and the covering. The interspace is filled with an underfiller material is disclosed.

### CROSS-REFERENCE TO RELATED APPLICATIONS

This Utility Patent Application claims priority to German Patent Application No. DE 10 2006 005 994.8 filed on Feb. 8, 2006, and U.S. Provisional Patent Application No. 60/771,245, filed Feb. 8, 2006, both of which are incorporated herein by reference.

### BACKGROUND

The invention relates to a semiconductor component having a semiconductor chip and to a method for producing semiconductor components.

Furthermore, the invention relates to a semiconductor wafer having a plurality of semiconductor chips, and to a panel having a plurality of semiconductor component positions, semiconductor chips having a covering forming a cavity above corresponding area regions being arranged in the semiconductor component positions. The invention also relates to methods for producing a suitable semiconductor wafer, a suitable panel and a plurality of semiconductor components.

Increasing miniaturization, particularly in the case of microelectromagnetic and microelectromechanical systems, requires covering, shielding and/or resonance structures made from materials whose structure is complex and whose mounting requires complicated auxiliary tools, which at the same time imposes limits on the degree of miniaturization for covering, shielding and/or resonance structures.

Assembly, in the course of which each covering, shielding and/or resonance element is to be applied individually on a semiconductor substrate, is furthermore cost-intensive. One solution is known from document DE 102 56 116 A1, in which a self-supporting electrically conductive covering layer is arranged above an active area region on a semiconductor chip and forms a cavity above the area region.

Considerable problems occur in the case of this solution, however, if a compact plastic housing composition which is shaped under high pressure and which is intended to protect the semiconductor component and the covering against external damage is to be provided for a semiconductor component of this type. The high pressure of 8 MPa to 10 MPa occurring in this case destroys the pressure-sensitive covering and thus the semiconductor component.

Document DE 103 53 767 discloses a device for housing a micromechanical structure and a method for producing the same, in which a photoresist forming the cavity is provided as sacrificial material in uncrosslinked fashion in the region of the cavity. For this purpose, the uncrosslinked photoresist is surrounded by a crosslinked photoresist region with an opening via which the uncrosslinked sacrificial material can be removed by solvents, so that a housing structure made from crosslinked photoresist is finally present.

This device also has the disadvantage that openings for removing the sacrificial material in the form of uncrosslinked photoresist are likewise necessary in order to ensure the cavity for the housing process. Furthermore, a costly method is required to realize such a component with a cavity. Finally, this cavity structure, too, does not withstand embedding in a plastic housing composition if it is done by working with an injection molding method with a fabrication pressure of 8 MPa to 10 MPa.

Document DE 103 16 776 discloses a method for producing a protective covering for a component, in which photoresists are used and a cavity structure is produced by removal of a sacrificial material via an opening in a covering layer made from highly crosslinked photoresist. Semiconductor components having such a pressure-sensitive cavity structure have the disadvantage that they do not withstand a subsequent fabrication pressure of between 8 MPa and 10 MPa for embedding in a plastic housing composition and, consequently, are not suitable for integration with other semiconductor elements in a common plastic housing composition.

For these and other reasons, there is a need for the present invention.

### SUMMARY

One embodiment provides a semiconductor having a semiconductor substrate having an active area region, a covering configured to protect the active area region, and a carrier. An interspace is located between the carrier and the covering. The interspace is filled with an underfiller material.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1 to 4 illustrate schematic cross sections through a panel during application and packaging of semiconductor chips to form semiconductor components.

FIG. 1 illustrates a schematic cross section through a circuit carrier with semiconductor component positions and semiconductor chips arranged above them.

FIG. 2 illustrates a schematic cross section through the circuit carrier in accordance with FIG. 1 after the application of the semiconductor chips in the semiconductor component positions.

FIG. 3 illustrates a schematic cross section through the circuit carrier in accordance with FIG. 2 after the application of an underfiller material.

FIG. 4 illustrates a schematic cross section through the circuit carrier in accordance with FIG. 3 after the application of a plastic housing composition.

FIG. 5 illustrates a schematic cross section through a semiconductor component in accordance with one embodiment of the invention.

FIG. 6 illustrates a schematic cross section through the semiconductor component after the application of external contacts.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The invention relates to a semiconductor component having a semiconductor chip and to a method for producing semiconductor components. In one embodiment, the semiconductor component is intended to be used in particular as a BAW filter (bulk acoustic wave filter), as a resonator, as a sensor or as an actuator in microelectromechanical systems, also called MEMs. For this purpose, an active top side of the semiconductor chip has an active area region covered by a self-supporting covering.

One or more embodiments provide a semiconductor component which increases the degree of miniaturization for covering, shielding and/or resonance structures and at the same time enables the semiconductor component to be protected in a manner that exhibits a high loading capacity in the form of a plastic housing composition shaped under high pressure, without damage to the miniaturized covering.

One embodiment provides a semiconductor component having a semiconductor chip, that includes a semiconductor substrate having an active top side, an active area region on the active top side and contact areas which surround the active area region and are electrically connected to the active area region. The active area region is protected by a self-supporting covering, which forms a cavity above the active area region. The height of the cavity corresponding to the thickness of a photoresist layer customary for semiconductor wafers. Flip-chip contacts are arranged on the contact areas, the flip-chip contacts projecting above the covering and being fixed on contact pads of a circuit carrier of the semiconductor component. The interspace between circuit carrier and semiconductor chip is filled with an electrically insulating underfiller material, which forms edge sides. The top side of the circuit carrier that has not been covered by the underfiller material and is thus the remainder of the top side, the edge sides of the underfiller material and the edge sides of the semiconductor chip are encapsulated by a plastic housing composition.

One difference this semiconductor component has over the semiconductor component from the prior art in accordance with DE 102 56 116 A1 is that instead of a thin plastic housing composition that is arranged above the covering layer in the case of the known semiconductor component, now an underfiller material protects the covering against damage, so that this semiconductor chip with its flip-chip contacts and the sensitive active area region and also with its pressure-sensitive covering made from a crosslinked photoresist layer is protected by an additional plastic housing composition which encapsulates the entire semiconductor chip at a high compression pressure and nevertheless does not damage the covering protected by the underfiller material in the interspace between the top side of the semiconductor chip and the top side of the circuit carrier.

A highly filigree semiconductor component is thus created, the construction of which in the active area region is protected by a cavity a few micrometers high, while a solid plastic housing composition resistant to high pressure protects the semiconductor component against damage. In this case, the photoresist has benzocyclobutene (BCB), polybenzoxazole (PBO), epoxy resin or polyimide (PI).

In one embodiment, it is provided that there is arranged on the circuit carrier a wiring structure having wiring lines leading from contact pads via through contacts through the circuit carrier to external contact areas. Furthermore, surface-mountable external contacts such as solder balls, solder bumps and/or galvanically applied pillar-type or parallelepipedal external contacts may be arranged on the external contact areas. Such a semiconductor component has one advantage that, independently of the production of the semiconductor chips, corresponding circuit carriers can be prepared which have a plurality of semiconductor component positions with the features specified above, such as the wiring structure, the through contacts and/or the external contact areas. Moreover, an increased degree of integration is possible by virtue of the fact that, in addition to the semiconductor chip with a cavity structure, further semiconductor chips can be embedded in the plastic housing composition.

In another embodiment, the underfiller material includes a curable synthetic resin that can be introduced without pressure into the interspace by capillary action, an as yet non-cured epoxy resin. Such an underfiller material that can be introduced in capillary fashion between the top side of the semiconductor chip with the covering according to the invention and the top side of the circuit carrier has the advantage that, in the edge regions of the semiconductor chip, a meniscus forms as the edge side of the underfiller material, and ensures that the filigree structure of the microscopically small cavity does not experience any damage in the course of encapsulation at an elevated pressure with a plastic housing composition.

In this context, microscopically small cavity is understood to be a cavity which is only a few micrometers in size and can thus only be measured precisely under a light-optical microscope. As a result of the pressure-free filling and encapsulation of the cavity housing made from a covering and a cavity by, e.g., a casting resin that is subsequently cured, it is possible to increase the durability of the flip-chip-bonded chip on the circuit carrier by a multiple compared with the electronic components known from the prior art. Moreover, the design of the active area region, becomes less dependent on the fabrication technology, since the protection can also be ensured for larger coverings by an underfiller material. Consequently, significantly larger areas can be spanned with the thickness of the covering remaining the same. In one or more embodiments, this is suitable when it is technologically impossible to further reinforce and configure the covering with increasing thickness, which is simultaneously associated with a higher outlay in respect of costs. Moreover, the covering is relieved of external loads by the underfiller material.

Such active area regions protected by a cavity are used for front end modules for mobile radio devices or as a power amplifier module of such a mobile radio device and/or as a filter module. For this purpose, structures whose dimensions are minimized down into the nanometers range are produced in the active area region on the active top side of the semiconductor substrate.

In a further embodiment, the invention relates to a semiconductor wafer having semiconductor component positions arranged in rows and columns with active area regions on an active top side of the semiconductor wafer. In the semiconductor chip positions, contact areas surround the active area region, the active area region being connected to the contact areas via wiring lines. Moreover, the active area regions in the semiconductor component positions of the semiconductor wafer are protected by a self-supporting covering, which forms a cavity above the active area region. In this case, as already discussed above for the semiconductor chip, the height of the cavity corresponds to a thickness corresponding to the customary thicknesses of photoresist layers on a semiconductor wafer.

On a semiconductor wafer, the flip-chip contacts may already be arranged on the contact areas, particularly when parallelepipedal or pillar-type flip-chip contacts are involved, which can be electrodeposited on the entire semiconductor wafer for a multiplicity of semiconductor chips.

A further embodiment relates to a panel having semiconductor component positions arranged in rows and columns. In this case, the semiconductor component positions have a semiconductor chip. The semiconductor chip has a semiconductor substrate with an active top side, an active area region on the active top side and contact areas which surround the active area region and are electrically connected to the active area region. A self-supporting covering is arranged on the active area region, the covering forming a cavity above the active area region.

The height of the cavity also corresponds to the customary thicknesses of photoresist layers on semiconductor wafers. On the panel, the semiconductor chips are arranged with their flip-chip contacts “face down” on a circuit carrier of the panel in the respective semiconductor component positions, the contact areas having flip-chip contacts which, for their part, are arranged on contact pads of the top side of the circuit carrier. The interspace between the circuit carrier and the semiconductor chip is filled with an electrically insulating underfiller material, which forms edge sides, each of the semiconductor chips on the circuit carrier in the semiconductor component positions, at its edge sides, forming a meniscus made from underfiller material, which seals the interspace between semiconductor chip and circuit carrier. This protects the sensitive region of the covering on the active top side of the semiconductor chip in such a way that the panel may have a plastic housing composition that extends over a plurality of semiconductor component positions and is applied under high pressure. Consequently, the panel is a composite board having circuit carrier, semiconductor chips, underfiller material and plastic housing composition.

There is arranged on the circuit carrier a wiring structure having wiring lines leading from contact pads in each of the semiconductor component positions via through contacts through the circuit carrier to external contact areas, surface-mountable external contacts being arranged on the external contact areas. The underfiller material is introduced in each of the semiconductor chips in the individual semiconductor component positions by capillary action and has a non-cured, low-viscosity epoxy resin.

One method for producing a semiconductor wafer having a plurality of semiconductor component positions is as follows. A semiconductor wafer having a plurality of semiconductor chip positions arranged in rows and columns is produced. This is followed by the production of active area regions in the semiconductor chip positions on the active top side of the semiconductor wafer with application of contact areas outside the active area regions. By photolithography, cavity structures are produced on the active area regions by known technologies, so that thin cavities protected by a covering spaced apart from the area region arise above the active area regions. It is also possible for flip-chip contacts to be applied to the contact areas which surround the active area region, and for the semiconductor wafer to be separated into individual semiconductor chips. Semiconductor chips are thus available which can then be used for producing a panel or for producing individual semiconductor components.

In one embodiment, uncrosslinked photoresist structures are used for a sacrificial layer if the covering includes a crosslinked photoresist. These sacrificial layers having uncrosslinked photoresist layers may subsequently be removed with the aid of solvents through an opening in the covering.

In a method for producing a panel having a plurality of semiconductor component positions, as discussed above, a semiconductor wafer is produced. Afterward, the semiconductor chips with flip-chip contacts arranged thereon and a cavity which is arranged on active area regions and is protected by a covering are fixed on corresponding semiconductor component positions of a circuit carrier. In preparatory fashion there is applied on the circuit carrier a wiring structure having contact pads, onto which the flip-chip contacts of the semiconductor chips can be soldered or adhesively bonded in the individual semiconductor component positions.

The interspace in the semiconductor component positions between the semiconductor chips and the circuit carrier of the panel is filled by pressure-free underfilling with an underfiller material until, at the edge sides of the semiconductor chips, corresponding menisci of the underfiller material form as edge sides of the underfiller material. In this case, the capillary action of low-viscosity but curable synthetic resins is used to fill the interspace as far as possible without pressure. Afterward, at least the free residual top sides of the circuit carrier, the edge sides of the underfiller material and the edge sides of the semiconductor chips are encapsulated with a plastic housing composition under compression pressure and with formation of a composite board as panel.

For a method for producing a plurality of semiconductor components, the resulting panel is then merely separated into individual semiconductor components. The application of the plastic housing composition is carried out at a pressure of 8 MPa to 10 MPa. This high loading can be withstood by the covering above the active area region of the individual semiconductor chips of a panel only when the underfiller material applied without any pressure has previously been cured and thus protects the pressure-sensitive covering.

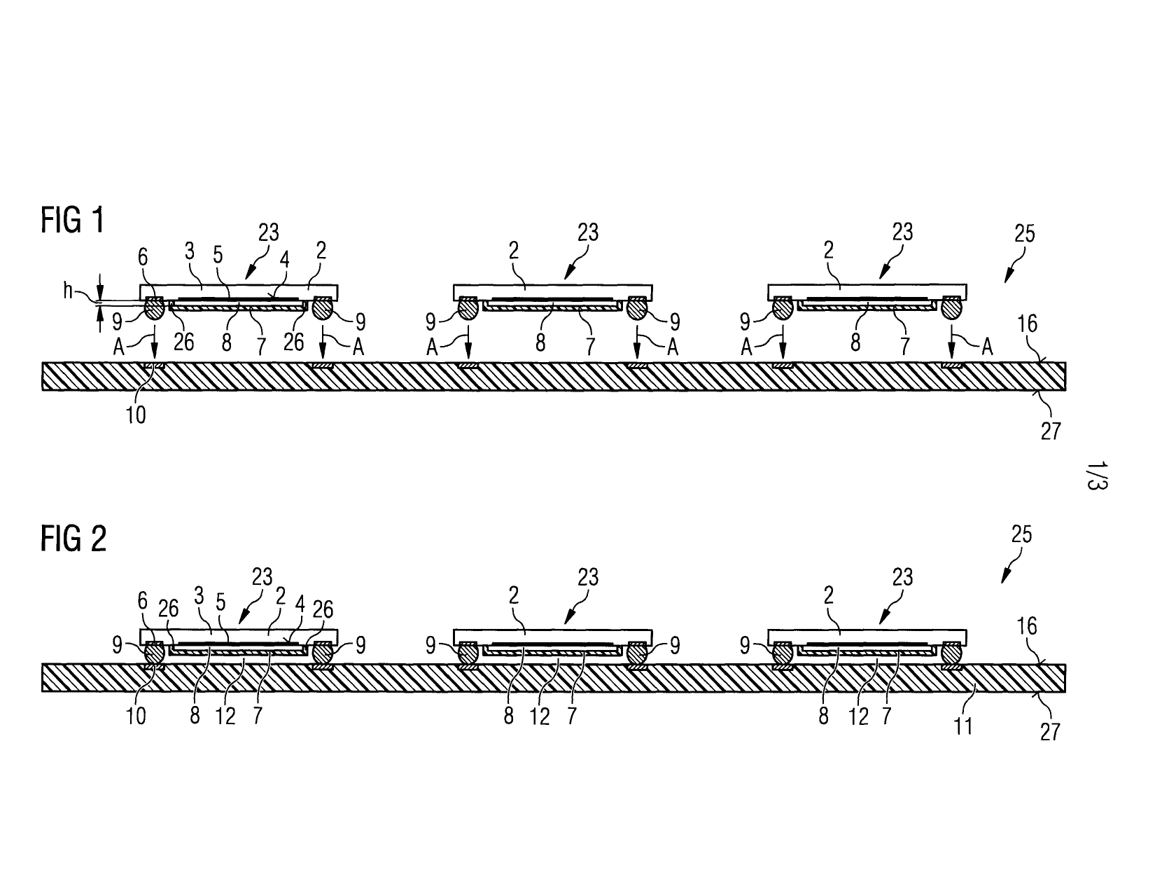

FIG. 1 illustrates a schematic cross section through a circuit carrier 11 with semiconductor component positions 23 and semiconductor chips 2 arranged above them. The semiconductor chips 2 have a semiconductor substrate 3 having an active area region 5, above which is arranged a cavity 8 covered by a self-supporting covering 7. The self-supporting covering 7 is supported on spacers 26 in the edge regions of the active area region 5, thereby ensuring a minimum cavity height h in the micrometer range. The cavity height h has resulted from the deposition of a patterned sacrificial layer made from uncrosslinked photoresist on a semiconductor wafer having this semiconductor chip 2.

On the active top side 4 of the semiconductor chip 2, contact areas 6 are arranged outside the active area region 5, flip-chip contacts 9 being fixed on the contact areas. The flip-chip contacts 9 project beyond the self-supporting covering 7, so that they can be fixed by soldering or adhesive bonding on the contact pads 10 of the circuit carrier 11 that are arranged underneath. For this purpose, the circuit carrier 11 has, on its top side 16, contact pads 10 of this type which, in terms of spacing and size and arrangement, correspond to the spacing and the size and the arrangement of the flip-chip contacts 9 of the semiconductor chip 2. For this purpose, as illustrated in FIG. 1, a semiconductor chip 2 is lowered in arrow direction A in each of the semiconductor component positions 23, so that the flip-chip contacts 9 can be fixed on the contact pads 10 of the circuit carrier 11.

FIG. 2 illustrates a schematic cross section through a circuit carrier 11 in accordance with FIG. 1 after the application of the semiconductor chips 2 in the semiconductor component positions 23. For this purpose, the flip-chip contacts 9 can be soldered on the contact pads 10 on the top side 16 of the circuit carrier 11. In this case, an interspace 12 or a gap arises between the top side 4 of the semiconductor chip 2 and the top side 16 of the circuit carrier 11. The interspace 12 is reduced by the cavity 8 and the associated covering 7, so that it is possible, by capillary action, to fill the interspace 12 with a non-cured synthetic resin of correspondingly low viscosity with formation of a meniscus in the edge regions of the semiconductor chips 2.

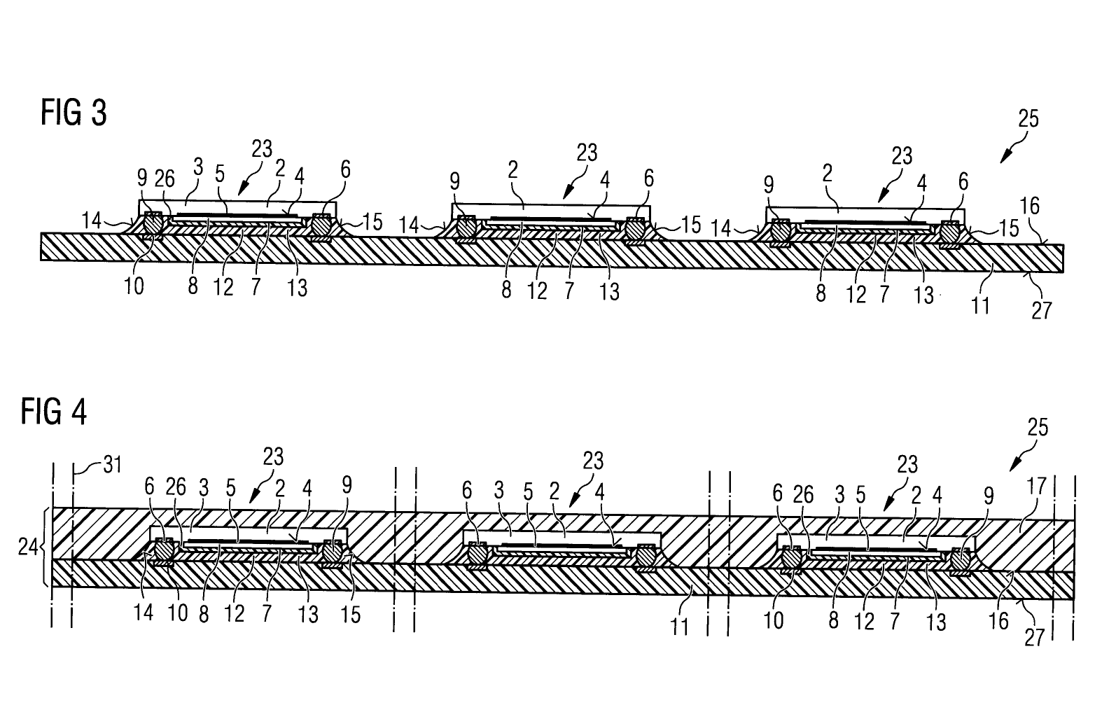

FIG. 3 illustrates a schematic cross section through the circuit carrier 11 in accordance with FIG. 2 after the application of an underfiller material 13. The underfiller material 13 is chosen in such a way that it wets correspondingly well both the top side 16 of the circuit carrier 11 and the active top side 4 of the semiconductor chip 2 and also the surfaces of the flip-chip contacts 9 and the top sides of the covering 7. On account of the high wettability of these surfaces by the underfiller material 13, a capillary action results on account of the surface tensions of the low-viscosity underfiller material 13 and completely fills the interspace 12 between the semiconductor chip and the circuit carrier 11.

In this embodiment, a meniscus made from underfiller material 13 arises in the edge regions of the semiconductor chip 2 and of the underfiller material 13 and has a convex contour after curing on account of the wettability. On account of the capillary action, it is possible for the underfiller material 13 to fill the interspace 12 without any pressure, without loading the thin covering 7 and without altering the cavity 8. After the curing of the underfiller material at temperatures of between 80° C. and 150° C., it is then possible to produce a mechanical stable plastic housing. The latter may be implemented by applying a curable plastics composition at a pressure of between 8 MPa and 10 MPa without damaging the covering 7 or the cavity 8.

FIG. 4 illustrates a schematic cross section through the circuit carrier 11 in accordance with FIG. 3 after the application of a plastic housing composition 17. With the application of the plastic housing composition 17 whilst encapsulating the residual surfaces 16 of the circuit carrier 11 and also whilst encapsulating the edge sides 14 and 15 of the underfiller material and also the edge sides 28 and 29 of the semiconductor chips and, in this embodiment of the invention, also the rear sides 30 of the semiconductor chips 2 under pressure, a composite board 24 arises. This composite board 24 constitutes a panel 25, which can be separated into individual semiconductor components along the dash-dotted lines 31.

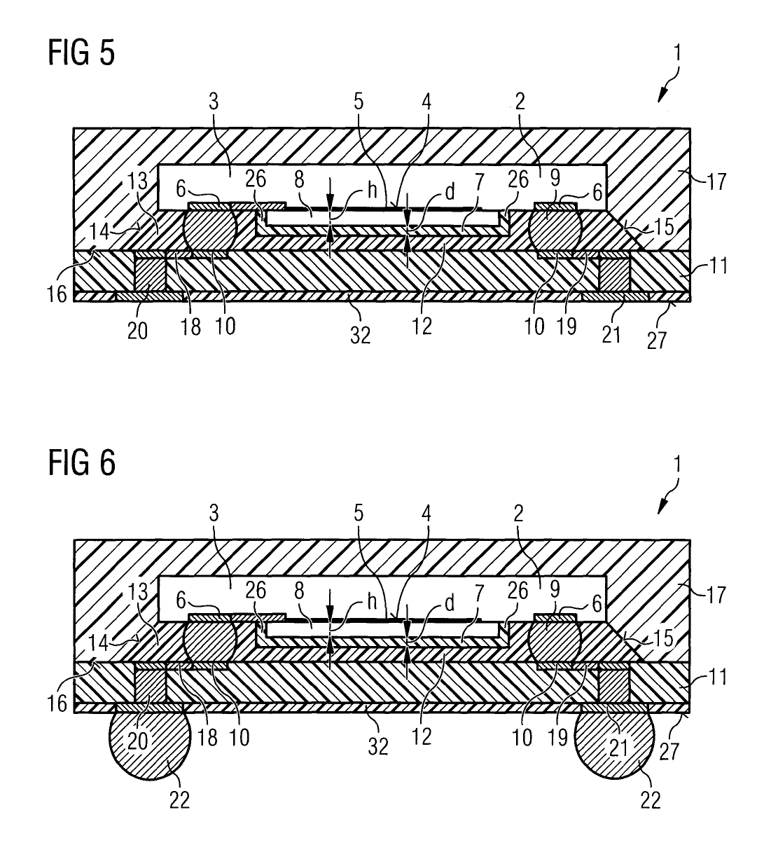

FIG. 5 illustrates a schematic cross section through a semiconductor component 1 in accordance with one embodiment. Components having functions identical to those in FIGS. 1 to 4 are identified by the same reference symbol and are not explained separately. The components of the semiconductor component 1 are embedded in a plastic housing composition 17, the top side 4 of the semiconductor chip 2 with the cavity 8 with a height h on the one hand being protected by a covering 7 having a thickness d in an active area region 5, and on the other hand an underfiller composition 13 surrounding the covering 7 in pressure-protected fashion.

At the same time, the underfiller composition 13 also encloses the flip-chip contacts 9 of the semiconductor chip, the flip-chip contacts 9 being arranged on contact pads 10 of the top side 16 of the circuit carrier 11. There is additionally arranged on the top side 16 a wiring structure 18 having wiring lines 19 which connect the contact pads 10 to through contacts 20 through the circuit carrier 11 and merge into external contact areas 21 on the underside 27 of the circuit carrier. The external contact areas are surrounded by a soldering resist layer 32.

FIG. 6 illustrates a schematic cross section through the semiconductor component 1 after the application of external contact areas 22 to the external contact areas 21. In this case, the soldering resist layer 32 ensures that the soldered-on external contact 22 only wets the external contact areas 21. This semiconductor component 1 is distinguished by the fact that it has a cavity 8 of minimal height h above an active area region 5 which is surrounded by a covering layer 7 of minimal thickness d, and this semiconductor component is nevertheless protected against damage by a solid plastic housing composition 17, the plastic housing composition 17 having been applied at a high excess pressure of between 8 MPa and 10 MPa without the pressure-sensitive thin covering layer 7 having been damaged. Such a semiconductor component 1 having such a cavity 8 of minimal height h is used for all semiconductor components where a high assembly output is required and where flip-chip contact technologies are sought for all components and where BAW modules are used.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor comprising:
a semiconductor substrate having an active area region;
a covering configured to protect the active area region;
a carrier;
an interspace between the carrier and the covering, filled with an underfiller material.

2. The semiconductor of claim 1, comprising:
the underfiller material comprising an electrically insulating material.

3. The semiconductor of claim 1, comprising:
the underfiller material comprising a cured synthetic resin introduced into the interspace without pressure.

4. The semiconductor of claim 3, comprising where the underfiller material is an epoxy resin.

5. The semiconductor of claim 1, comprising:
a plastic housing encapsulating the semiconductor substrate and edges of the underfiller material, and contacting a portion of the carrier.

6. The semiconductor of claim 1, comprising:
the covering being a self-supporting covering.

7. The semiconductor of claim 1, comprising:
a cavity defined by a space between the active area region and the covering.

8. The semiconductor of claim 1, comprising:
the covering including spacers configured to space the active area region from the covering, defining the cavity.

9. The semiconductor of claim 1, comprising:
the covering comprising a photoresist.

10. A semiconductor component having a semiconductor chip, comprising:
a semiconductor substrate having an active top side, an active area region on the active top side and contact areas which surround the active area region and are electrically connected to the active area region;
a covering protecting the active area region, the covering forming a cavity above the active area region;
a circuit carrier;
contacts projecting between the contact pads and the circuit carrier; and
where an interspace between the circuit carrier and semiconductor chip is filled with an electrically insulating underfiller material having edge sides, and the edge sides of the underfiller material and the semiconductor chip being encapsulated by a plastic housing composition.

11. The semiconductor component of claim 10, comprising:
a wiring structure with wiring lines is arranged on the circuit carrier, the wiring lines leading from contact pads via through contacts through the circuit carrier to external contact areas, surface-mountable external contacts being arranged on the external contact areas.

12. The semiconductor component of claim 10, wherein the underfiller material comprises a curable synthetic resin that can be introduced without pressure into the interspace by capillary action.

13. The semiconductor component of claim 10, wherein the covering comprises a cured, crosslinked photoresist.

14. The semiconductor component of claim 10, wherein the active area region comprises a sensor with an MEM structure, a BAW filter, a microphone or micropatterned actuators.

15. The semiconductor component of claim 10, wherein the active area region comprises a front end module of a mobile radio device or a power amplifier module of the mobile radio device and/or a filter module.

16. A semiconductor wafer comprising:
semiconductor chip positions arranged in rows and columns with active area regions on an active top side of the semiconductor wafer;
contact areas surrounding the active area region of a semiconductor chip position and being electrically connected to the active area region via wiring lines; and
a self-supporting covering configured to protect the active area region, and which forms a cavity above the active area region.

17. The semiconductor wafer of claim 16, comprising:
where the height of the cavity corresponding to the thickness of a photoresist layer customary for semiconductor wafers.

18. The semiconductor wafer according to claim 16, comprising wherein flip-chip contacts are arranged on the contact areas, the flip-chip contacts projecting above the covering.

19. The semiconductor wafer of claim 18, wherein the covering comprises a cured, crosslinked photoresist.

20. The semiconductor wafer of claim 16, wherein the active area region comprises a sensor with an MEM structure, a BAW filter, a microphone or micropatterned actuators.

21. A panel having semiconductor component positions arranged in rows and columns, one or more semiconductor component positions comprising:
a semiconductor chip, which comprises a semiconductor substrate having an active area region, a covering configured to protect the active area region, a carrier, an interspace between the carrier and the covering, filled with an underfiller material; and
a plastic housing composition encapsulating edge sides of the underfiller material and the semiconductor chip in the semiconductor component positions to defined a composite board is present.

22. The panel of claim 21, comprising wherein the covering has a thickness corresponding to a thickness of a cured and crosslinked photoresist layer.

23. The panel of claim 21, comprising wherein there is arranged on the carrier a wiring structure having wiring lines leading from contact pads via through contacts through the circuit carrier to external contact areas, surface-mountable external contacts being arranged on the external contact areas.

24. The panel of claim 21, comprising wherein the underfiller material comprises a curable synthetic resin that can be introduced without pressure into the interspace by capillary action.

25. The panel of claim 21, comprising wherein the active area region comprises a sensor with an MEM structure, a BAW filter, a microphone or micropatterned actuators.

26. The panel of claim 21, wherein the active area region comprises a front end module of a mobile radio device or a power amplifier module of the mobile radio device and/or a BAW filter module.

27. A method for producing a semiconductor wafer having a plurality of semiconductor chip positions, the method comprising:
producing a semiconductor wafer having a plurality of semiconductor chip positions arranged in rows and columns;
producing an active area region in the semiconductor chip positions on the active top side of the semiconductor wafer and applying of contact areas outside the active area region;
producing a cavity housing structure above the active area region by photolithography from a photoresist;
applying flip-chip contacts to the contact areas; and
separating the semiconductor wafer into individual semiconductor chips.

28. The method of claim 27, comprising applying a sacrificial layer made from a patterned, uncrosslinked and non-cured photoresist layer on the semiconductor wafer.

29. A method for producing a panel having a plurality of semiconductor component positions, the method comprising:
producing a semiconductor wafer having a plurality of semiconductor chip positions arranged in rows and columns;
producing an active area region in the semiconductor chip positions on the active top side of the semiconductor wafer and application of contact areas outside the active area region;
producing a cavity housing structure above the active area region by photolithography from a cured and crosslinked photoresist;
applying flip-chip contacts to the contact areas;
separating the semiconductor wafer into individual semiconductor chips;
producing a circuit carrier having semiconductor component positions arranged in rows and/or columns, the semiconductor component positions comprising contact pads for electrical connection to flip-chip contacts of a semiconductor chip;
applying the semiconductor chips by their flip-chip contacts on the contact pads of the circuit carrier in the semiconductor component positions; and
pressure-free underfilling of the interspace between semiconductor chips and circuit carrier with a curable synthetic resin with formation of edge sides made from underfiller material.

30. The method of claim 29, comprising:
encapsulating at least the free top side of the circuit carrier, the edge sides of the underfiller material and the semiconductor chips with a plastic housing composition under compression pressure and with formation of a composite board as panel.

31. The method of claim 29, comprising applying a sacrificial layer on the semiconductor wafer made from a patterned, non-cured and uncrosslinked photoresist layer.

32. The method of claim 19, comprising wherein for the pressure-free underfilling of the interspace between semiconductor chips and circuit carrier with a curable synthetic resin, a low-viscosity synthetic resin, with the aid of capillary forces, fills the interspace with formation of a meniscus to form edge sides.

33. A method for producing a plurality of semiconductor components, the method comprising:
producing a semiconductor wafer having a plurality of semiconductor chip positions arranged in rows and columns;
producing an active area region in the semiconductor chip positions on the active top side of the semiconductor wafer and application of contact areas outside the active area region;
producing a cavity housing structure above the active area region by photolithography from a cured and crosslinked photoresist;
applying flip-chip contacts to the contact areas;
separating the semiconductor wafer into individual semiconductor chips;
producing a circuit carrier having semiconductor component positions arranged in rows and/or columns and having contact pads for electrical connection to flip-chip contacts of a semiconductor chip;
applying the semiconductor chips by their flip-chip contacts on the contact pads of the circuit carrier in the semiconductor component positions;
pressure-free underfilling of the interspace between semiconductor chips and circuit carrier with a curable synthetic resin with formation of edge sides made from underfiller material;
encapsulating at least the free top side of the circuit carrier, the edge sides of the underfiller material and the semiconductor chips with a plastic housing composition under compression pressure and with formation of a composite board as panel;
separating the panel into individual semiconductor components.

34. The method of claim 33, comprising wherein a sacrificial layer is applied on the semiconductor wafer made from a patterned, non-cured and uncrosslinked photoresist layer.

35. The method of claim 33, comprising wherein for the pressure-free underfilling of the interspace between semiconductor chips and circuit carrier with a curable synthetic resin, a low-viscosity synthetic resin, with the aid of capillary forces, fills the interspace with formation of a meniscus to form edge sides.

36. The method of claim 33, comprising wherein surface-mountable external contacts are applied on an underside of the circuit carrier before or after the separation of the panel into individual semiconductor components.
